(19) United States
(12) Patent Application Publication
(10) Pub. No.: US 2026/0271314 A1
(43) Pub. Date: Sep. 10, 2026

(54) SEMICONDUCTOR DEVICE

(71) Applicant: Mitsubishi Electric Corporation, Tokyo (JP)

(72) Inventors: Ayanori GATTO, Tokyo (JP); Shinya SONEDA, Tokyo (JP)

(73) Assignee: Mitsubishi Electric Corporation, Tokyo (JP)

(21) Appl. No.: 19/402,648

(22) Filed: Nov. 26, 2025

(30) Foreign Application Priority Data
Mar. 4, 2025 (JP) 2025-033614

(51) Int. Cl. H10D 12/00; H10D 62/10; H10D 62/60; H10D 64/00; H10D 84/80

(52) U.S. Cl. CPC H10D 12/212; H10D 62/107; H10D 62/126; H10D 62/60; H10D 64/112; H10D 64/117; H10D 84/811

(57) ABSTRACT

An object is to provide a technique capable of increasing a degree of freedom in designing a trench while suppressing an erroneous operation. A semiconductor device includes: an upper polysilicon layer provided to an upper part of a trench; and a lower polysilicon layer provided to a lower part of the trench and insulated from the upper polysilicon layer by an insulating film, wherein the upper polysilicon layer is electrically connected to a gate electrode, the lower polysilicon layer and the second semiconductor layer are electrically connected to an anode electrode, and a lower end of the second semiconductor layer is located below a lower end of the upper polysilicon layer.

### BACKGROUND

### Technical Field

The present disclosure relates to a semiconductor device.

### Description of the Background Art

For example, in a diode according to International Publication No. 2014/128950, lower end of a p⁻-type voltage withstanding layer provided on an N⁻-type drift layer and electrically connected to an anode electrode is located below a lower end of a gate electrode in a trench provided to the p⁻-type voltage withstanding layer. According to such a configuration, an erroneous operation in which an anode electrode and the N⁻-type drift layer are short-circuited.

### SUMMARY

However, in the above configuration, the lower end of the gate electrode, that is to say, a depth of the trench is restricted by a position of the lower end of the P⁻-type voltage withstanding layer; thus, there is a problem that a degree of freedom in designing the trench decreases.

The present disclosure therefore has been made to solve the above problems, and it is an object to provide a technique capable of increasing a degree of freedom in designing a trench while suppressing an erroneous operation.

A semiconductor device according to the present disclosure includes: a first semiconductor layer of a first conductivity type; a second semiconductor layer of a second conductivity type provided on an upper side of the first semiconductor layer; an insulating film provided on a trench with an opening in an upper surface of the second semiconductor layer and provided between an upper part and a lower part of the trench; an upper polysilicon layer provided to the upper part of the trench; and a lower polysilicon layer provided to the lower part of the trench and insulated from the upper polysilicon layer by the insulating film, wherein the upper polysilicon layer is electrically connected to a gate electrode, the lower polysilicon layer and the second semiconductor layer are electrically connected to an anode electrode, and a lower end of the second semiconductor layer is located below a lower end of the upper polysilicon layer.

A degree of freedom in designing a trench can be increased while an erroneous operation is suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to an embodiment 1.

FIG. 2 is a cross-sectional view illustrating a configuration of the semiconductor device according to the embodiment 1.

FIG. 3 is a cross-sectional view illustrating a configuration of a related device.

FIG. 4 is a circuit diagram schematically illustrating a circuit using the semiconductor device according to the embodiment 1.

FIGS. 5A and 5B are diagrams each illustrating a waveform of a gate signal Vi and a gate signal Vd.

FIG. 6 is a diagram for explaining a recovery loss Erec.

FIG. 7 is a diagram illustrating dependency of the regulated recovery loss Erec on delay time dt.

FIG. 8 is a diagram illustrating dependency of the regulated recovery loss Erec on delay time dt.

FIG. 9 is a cross-sectional view illustrating a configuration of a semiconductor device according to a modification example of the embodiment 1.

FIG. 10 is a plan view illustrating a configuration of a semiconductor device according to an embodiment 2.

FIG. 11 is a cross-sectional view illustrating a configuration of the semiconductor device according to the embodiment 2.

FIG. 12 is a cross-sectional view illustrating a configuration of a semiconductor device according to a modification example of the embodiment 2.

FIG. 13 is a cross-sectional view illustrating a configuration of a semiconductor device according to an embodiment 3.

### DESCRIPTION OF THE PREFERRED EMBODIMENTS

Embodiments are described with reference to the appended diagrams hereinafter. Features described in each embodiment described below is exemplification, thus all features are not necessarily applied. The same or similar reference numerals will be assigned to similar constituent elements in a plurality of embodiments in the description hereinafter, and the different constituent elements are mainly described hereinafter. A specific position and direction such as “upper”, “lower”, “left”, “right”, “front”, or “back”, for example, may not necessarily coincide with a position and direction in an actual implementation in the description hereinafter. Although a first conductivity type is an N type and a second conductivity type is a P type in the description hereinafter, it is also applicable that the first conductivity type is a P type and the second conductivity type is an N type.

### Embodiment 1

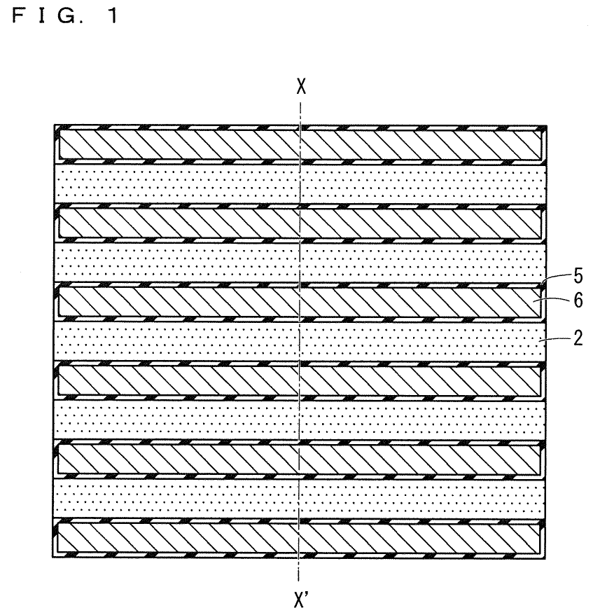

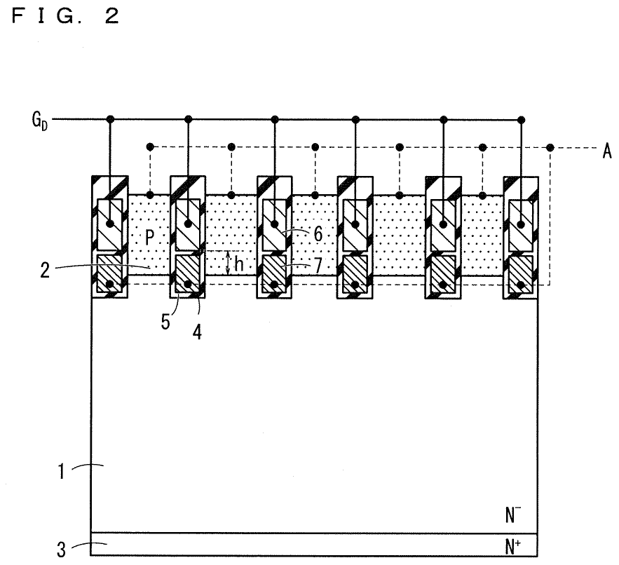

FIG. 1 is a plan view illustrating a configuration of a semiconductor device according to the present embodiment 1, and FIG. 2 is a cross-sectional view illustrating the configuration of the semiconductor device along an X-X′ line in FIG. 1. The semiconductor device according to the present embodiment 1 corresponds to a diode having a gate structure similar to that of a MOSFET, and includes a pin diode and a diode of a reverse conducting-IGBT (RC-IGBT), for example.

The semiconductor device in FIG. 2 includes an N⁻-type layer 1 as an N-type first semiconductor layer, a P-type layer 2 as a P-type second semiconductor layer, an N⁺-type layer 3 having an N type, an oxide film 5 as an insulating film, an upper polysilicon layer 6, and a lower polysilicon layer 7.

The P-type layer 2 is provided on an upper side of the N⁻-type layer 1. A peak concentration of the N-type impurity of the N⁻-type layer 1 is equal to or higher than 10¹² cm⁻³ and equal to or lower than 10¹⁴ cm⁻³, for example, and sufficient withstand voltage is ensured. A peak concentration of the P-type impurity of the P-type layer 2 is equal to or higher than 10¹⁵ cm⁻³, for example, and sufficient power conduction is ensured. A peak concentration of the P-type impurity of the P-type layer 2 is equal to or lower than 10¹⁷ cm⁻³, for example, and reduction of a recovery block capacity is suppressed.

The N⁺-type layer 3 is provided on a lower side of the N⁻-type layer 1. A concentration of the N-type impurity of the N⁺-type layer 3 is higher than that of the N-type impurity of the N⁻-type layer 1, and a peak concentration thereof is equal to or higher than 10¹⁷ cm⁻³; for example. Thus, sufficient power conduction is ensured.

The N⁻-type layer 1, the P-type layer 2, and the N⁺-type layer 3 may be made up of a normal semiconductor wafer or an epitaxial growth layer. The N⁻-type layer 1, the P-type layer 2, and the N⁺-type layer 3 may be made of normal silicon (Si), or may also be made of a wide bandgap semiconductor such as silicon carbide (SiC), gallium nitride (GaN), gallium oxide (Ga₂O₃), or diamond. When N⁻-type layer 1, the P-type layer 2, and the N⁺-type layer 3 are made up of the wide bandgap semiconductor, a stable operation at high temperatures and high voltages and increased switching speed can be achieved.

A trench 4 has an opening in an upper surface of the P-type layer 2. Although the trench 4 is provided to the P-type layer 2 at regular intervals in the example in FIG. 1, the configuration is not limited thereto.

As illustrated in FIG. 2, the oxide film 5 is provided on the trench 4 and provided between an upper part and a lower part of the trench 4. For example, it is applicable that the oxide film 5 includes a first oxide film provided on the trench 4, a second oxide film provided between the upper part and the lower part of the trench 4, and a third oxide film provided on the upper polysilicon layer 6, and the first oxide film, the second oxide film, and the third oxide film are individually formed.

The upper polysilicon layer 6 is provided to the upper part of the trench 4, and is surrounded by the oxide film 5 in a cross-sectional view. The lower polysilicon layer 7 is provided to the lower part of the trench 4, and is surrounded by the oxide film 5 in a cross-sectional view. The upper polysilicon layer 6 and the lower polysilicon layer 7 are insulated from each other by the oxide film 5.

The upper polysilicon layer 6 is electrically connected to a gate electrode G_{D} of for a diode. The lower polysilicon layer 7 and the P-type layer 2 are electrically connected to an anode electrode A.

As illustrated in FIG. 2, a lower end of the P-type layer 2 is located below a lower end of the upper-polysilicon layer 6. In the present embodiment 1, a height h between the lower end of the P-type layer and the lower end of the upper polysilicon layer 6 is equal to or larger than 3 μm.

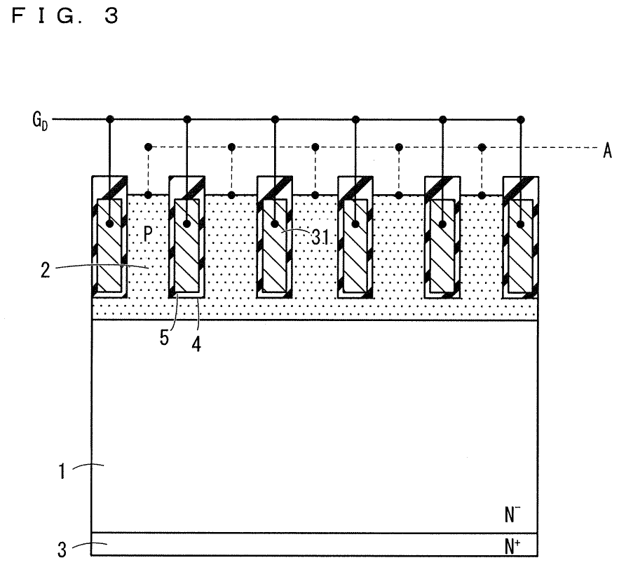

FIG. 3 is a cross-sectional view illustrating a configuration of a semiconductor device (referred to as “a related device” hereinafter) related to the semiconductor device 1 according to the present embodiment 1. Provided in the related device in FIG. 3 is a polysilicon layer 31 which is electrically connected to the gate electrode G_{D} for the diode and is not sectioned up and down in place of the upper polysilicon layer 6 and the lower polysilicon layer 7. The lower end of the P-type layer 2 is located below a lower end of the polysilicon layer 31.

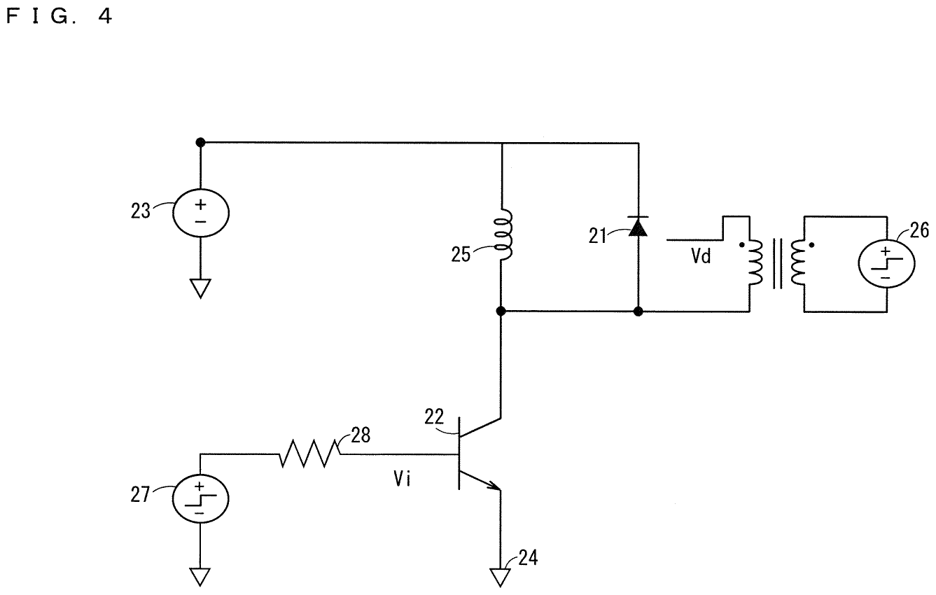

FIG. 4 is a circuit diagram schematically illustrating a circuit using the semiconductor device according to the present embodiment 1 or the related device. The semiconductor device according to the present embodiment 1 or the related device corresponds to a diode 21 in FIG. 4. A cathode terminal of the diode 21 is connected to a power source 23, and an anode terminal of the diode 21 is connected to one end of an insulated gate bipolar transistor (IGBT) 22, and the other end of the IGBT 22 is connected to a ground 24. One end of an inductance 25 is connected to the cathode terminal of the diode 21, and the other end of the inductance 25 is connected to the anode terminal of the diode 21. Although the diode 21 is connected to the IGBT in the example in FIG. 4, the configuration is not limited thereto. The diode 21 may be connected to a metal oxide semiconductor field effect transistor (MOSFET).

A signal generation part 26 in FIG. 4 inputs a gate signal Vd to the upper polysilicon layer 6 or the polysilicon layer 31 via the gate electrode G_{D} for the diode in FIG. 2 or FIG. 3. A signal generation part 27 in FIG. 4 inputs a gate signal Vi to a gate terminal of the IGBT 22 via resistance 28.

A carrier concentration on an anode side of the diode 21 is controlled by an on operation and an off operation of a gate on the anode side of the diode 21, that is to say, increase and decrease of the gate signal Vd. For example, when the diode 21 is a diode having a gate structure similar to that of an n channel MOSFET and performing power conduction operation, the off operation of the gate of the diode 21 is performed, and the gate signal Vd takes a negative value. Accordingly, since a hole is accumulated in the channel of the P-type layer 2 and is implanted into the N⁻-type layer 1, power conduction loss can be reduced.

For example, when the diode 21 is a diode having a gate structure similar to that of an n channel MOSFET and before the diode 21 performs recovery operation, the on operation of the gate of the diode 21 is performed, and the gate signal Vd takes a positive value. Since a PN junction of the anode is partially or completely short-circuited, or electrons is implanted into the N⁻-type layer 1 via the channel of the P-type layer 2, recovery loss can be reduced.

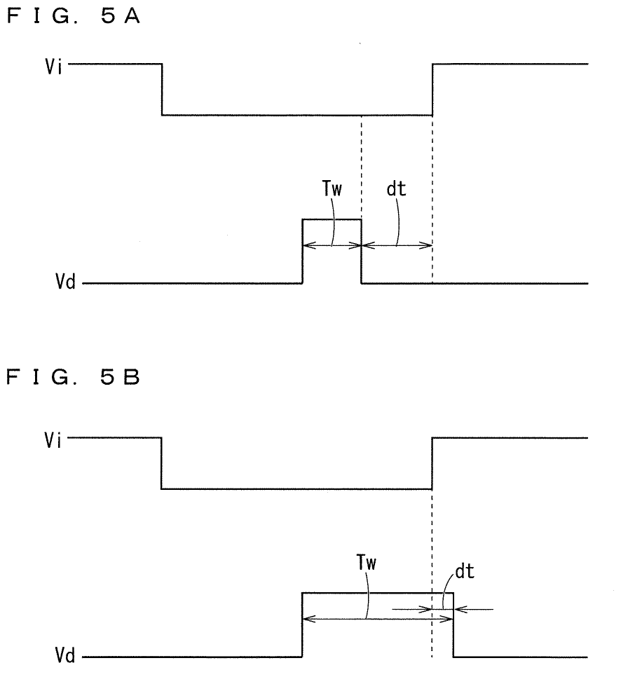

FIG. 5A and FIG. 5B are diagrams each illustrating a waveform of the gate signal Vi inputted to the IGBT 22 and the gate signal Vd inputted to the diode 21. A delay time dt is provided between a falling time of the gate signal Vd and a rising time of the gate signal Vi.

As illustrated in FIG. 5A, when the delay time dt>0 is satisfied, that is to say, when the falling time of the gate signal Vd is earlier than the rising time of the gate signal Vi, the gate of the IGBT 22 and the gate of the diode 21 are not turned on at the same time; thus, an erroneous operation of a circuit does not occur.

However, as illustrated in FIG. 5B, when a pulse width Tw of the gate signal Vd is large and the delay time dt<0 is satisfied, that is to say, when the falling time of the gate signal Vd is later than the rising time of the gate signal Vi, the gate of the IGBT 22 and the gate of the diode 21 are turned on at the same time. Differing from the configuration of FIG. 2 or FIG. 3, in a configuration that the lower end of the P-type layer 2 is located above the lower end of the upper polysilicon layer 6 or the polysilicon layer 31, when the gate of the diode 21 is turned on, the anode electrode A is short-circuited with the N⁻-type layer 1 via an electron accumulation layer of the channel of the P-type layer 2. When the gate of the IGBT 22 and the gate of the diode 21 are turned on at the same time as illustrated in FIG. 5B in such a configuration, current from the power source 23 in FIG. 4 flows from a cathode side to an anode side of the diode 21, and an erroneous operation of the circuit occurs.

However, in the semiconductor device according to the present embodiment 1, the lower end of the P-type layer 2 is located below the lower end of the upper polysilicon layer 6 as illustrated in FIG. 2, and in the related device, the lower end of the P-type layer 2 is located below the lower end of the polysilicon layer 31 as illustrate in FIG. 3. According to such a configuration, even when the gate of the diode 21 is turned on, a part deeper than the channel of the P-type layer 2 is not short-circuited. Thus, the short circuit of the anode electrode A with the N⁻-type layer 1 can be suppressed. Accordingly, current from the power source 23 in FIG. 4 flowing from the cathode side to the anode side of the diode 21 can be suppressed, and an erroneous operation of the circuit can be suppressed.

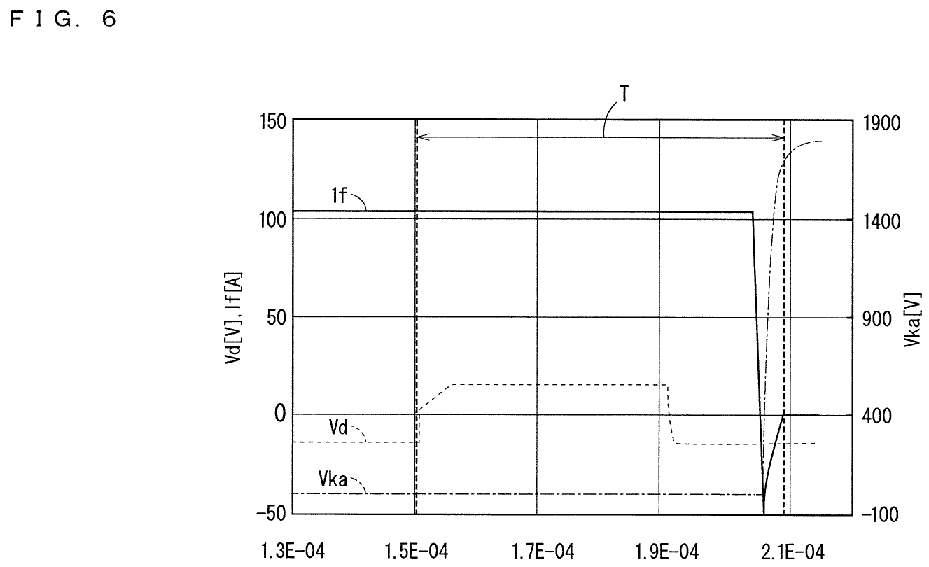

FIG. 6 is a diagram for explaining a recovery loss Erec as electrical power loss in recovery operation. FIG. 6 illustrates waveforms of current If, voltage Vka, and the gate signal Vd of the diode 21 in the recovery operation. The recovery loss Erec is electrical power loss at a period T from a point of time of turning on the gate signal Vd of the diode 21 to a point of time of turning off the current If. When the erroneous operation of the circuit described above occurs, a chip is short circuited, and the recovery loss Erec increases rapidly.

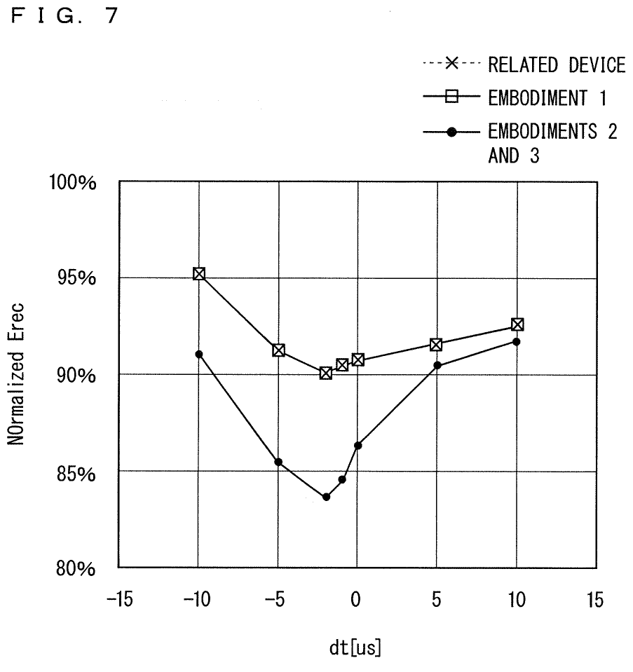

FIG. 7 is a diagram illustrating dependency of the regulated recovery loss Erec on the delay time dt. As illustrated in FIG. 7, the semiconductor device according to the present embodiment 1 has dependency similar to the related device, and the recovery loss Erec does not increase rapidly even when the delay time dt<0 is satisfied. Thus, in the semiconductor device according to the present embodiment 1 and the related device, the erroneous operation is suppressed even when the delay time dt<0 is satisfied, and the recovery operation can be achieved. The reason thereof is considered that, as described above, the part deeper than the channel of the P-type layer 2 is not short circuit, the short circuit of the anode electrode A with the N⁻-type layer 1 is suppressed, the current from the power source 23 in FIG. 4 flowing in the diode 21 is suppressed, and the erroneous operation of the circuit is suppressed.

Herein, in the related device in which the lower end of the P-type layer 2 is located below the lower end of the polysilicon layer 31, an upper limit of a depth of the trench 4 where the polysilicon layer 31 is provided is restricted by a position of the lower end of the P-type layer 2. Thus, a degree of freedom in designing the trench 4 gets low. Thus, there is a problem that the trench 4 of the diode 21 and the trench of the IGBT 22 cannot be formed at the same time, and the number of processes increases, for example. For example, there is a problem that when the lower end of the P-type layer 2 is designed to be moved to the lower side so that the trench 4 of the diode 21 and the trench of the IGBT 22 can be formed at the same time, a time of impurity diffusion for forming the P-type layer 2 gets long.

In the meanwhile, in the semiconductor device according to the present embodiment 1, even when the lower end of the P-type layer 2 is located below the lower end of the upper polysilicon layer 6, the depth of the trench 4 can be changed by changing the height of the lower polysilicon layer 7 which does not contribute to channel control. Since the upper limit of the depth of the trench 4 is not restricted by the position of the lower end of the P-type layer 2 in the present embodiment 1, the degree of freedom in designing the trench 4 can be increased. Although the lower end of the P-type layer 2 is located above the lower end of the lower polysilicon layer 7 in the example in FIG. 2, the configuration is not limited thereto. The lower end of the P-type layer 2 may be located below the lower end of the lower polysilicon layer 7.

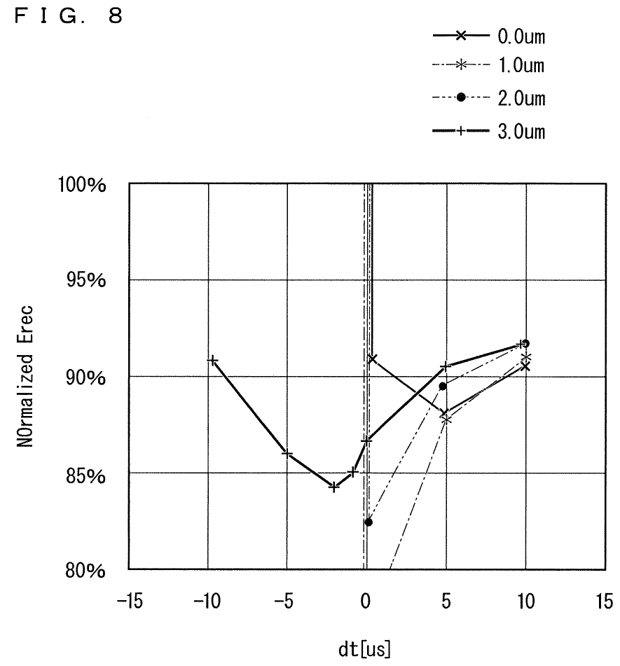

FIG. 8 is a diagram illustrating dependency of the regulated recovery loss Erec on the delay time dt with respect to the height h in FIG. 2. In a configuration that the height h is 0.0 μm, 1.0 μm, or 2.0 μm as illustrated in FIG. 8, the recovery loss Erec increases rapidly when the delay time dt is 0. In the meanwhile, in the present embodiment 1, the height h between the lower end of the P-type layer and the lower end of the upper polysilicon layer 6 is equal to or larger than 3 μm. Thus, increase of the recovery loss Erec can be suppressed.

### MODIFICATION EXAMPLE

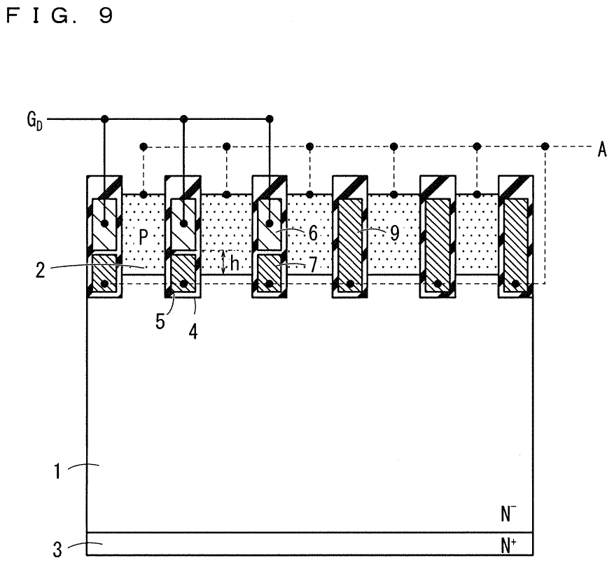

Although the upper polysilicon layer 6 and the lower polysilicon layer 7 are provided to all of the trenches 4 in the embodiment 1, the configuration is not limited thereto. It is also applicable that as illustrated in FIG. 9, for example, the upper polysilicon layer 6 and the lower polysilicon layer 7 are provided to some trenches 4, and a polysilicon layer 9 which is electrically connected to the anode electrode A and is not sectioned up and down is provided to the other trenches 4. According to such a configuration, a ratio of the polysilicon layer 9 to the upper polysilicon layer 6 and the lower polysilicon layer 7 is adjusted. Thus, a degree of effect of reducing recovery loss of the semiconductor device can be controlled.

### Embodiment 2

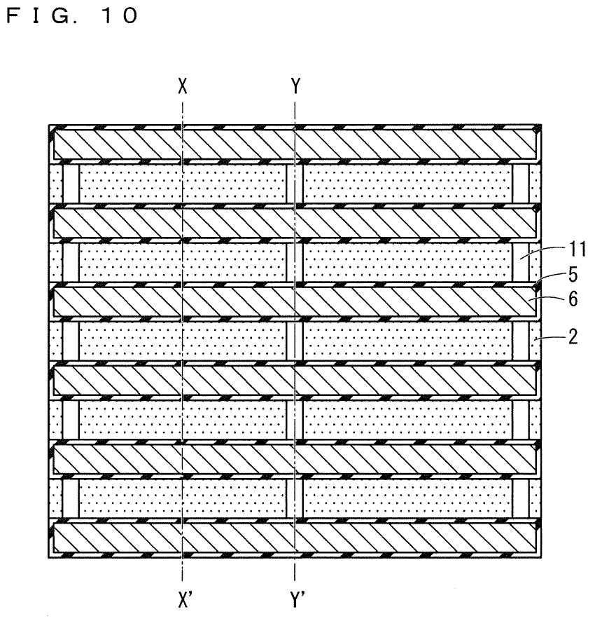

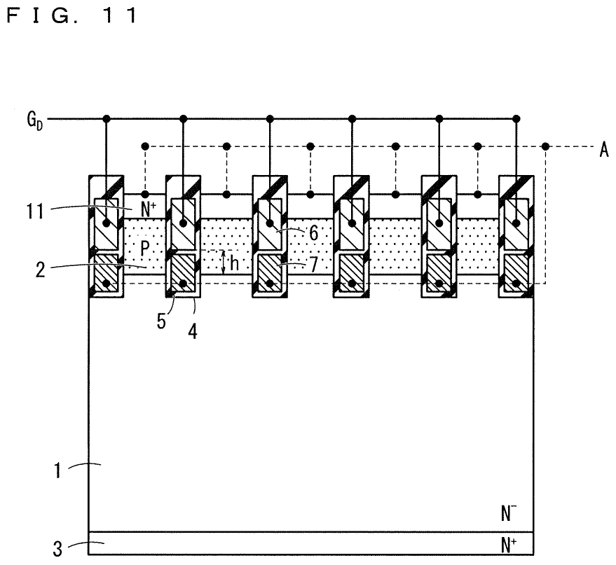

FIG. 10 is a plan view illustrating a configuration of a semiconductor device according to the present embodiment 2, and FIG. 11 is a cross-sectional view illustrating the configuration of the semiconductor device along a Y-Y′ line in FIG. 10. A configuration along an X-X′ line in FIG. 10 is similar to that in FIG. 2.

In the present embodiment 2, as illustrate in FIG. 10 and FIG. 11, an N⁺-type layer 11 as an N-type third semiconductor layer is selectively (that is to say, partially) provided to an upper part of the P-type layer 2, and is electrically connected to the anode electrode A. In the present embodiment 2, a peak concentration of an N-type impurity of the N⁺-type layer 11 is higher than that of the N-type impurity of the N⁻-type layer 1 and the P-type impurity of the P-type layer 2.

According to such a configuration, when the on operation of the gate of the diode is performed before the recovery operation, some of electrons implanted from the N⁺-type layer 11 is recombined with the hole from the P-type layer 2. Accordingly, as illustrated in FIG. 7, according to the present embodiment 2, increase of the recovery loss Erec can be suppressed compared with the embodiment 1.

### MODIFICATION EXAMPLE

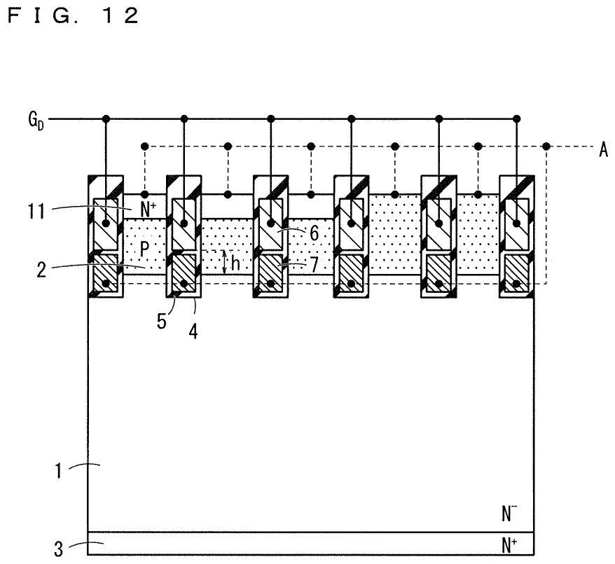

Although the N⁺-type layer 11 is provided to the upper part of all of the P-type layers 2 in a cross section in FIG. 11 according to the embodiment 2, the configuration is not limited thereto. For example, the N⁺-type layer 11 may be provided to the upper part of only some of the P-type layers 2 as illustrated in FIG. 12. According to such a configuration, a ratio between a part where the N⁺-type layer 11 is provided and a part of the N+-type layer 11 is not provided is adjusted. Thus, a degree of effect of reducing recovery loss of the semiconductor device can be controlled.

### Embodiment 3

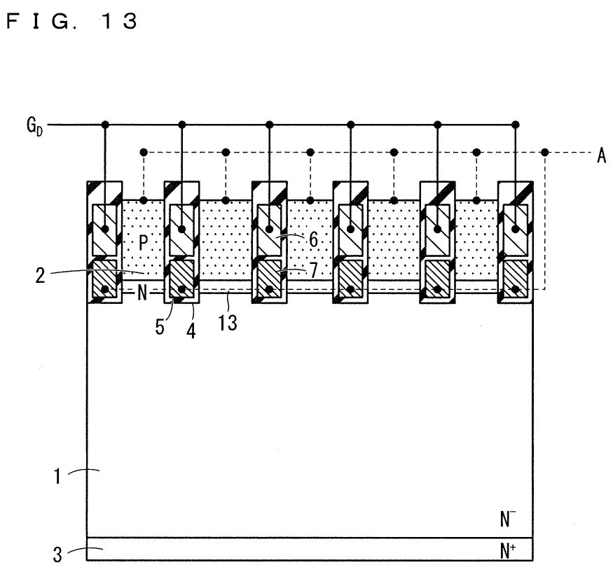

FIG. 13 is a cross-sectional view illustrating a configuration of a semiconductor device according to the present embodiment 3, and is a cross-sectional view corresponding to FIG. 2. In the present embodiment 3, an N-type layer 13 as an N-type fourth semiconductor layer is provided between the N⁻-type layer 1 and the P-type layer 2. A peak concentration of an N-type impurity of the N-type layer 13 is higher than that of the N-type impurity of the N⁻-type layer 1. A peak concentration of the N-type impurity of the N-type layer 13 is equal to or higher than 10¹⁷ cm⁻³, for example, and sufficient power conduction is ensured. A lower end of the N-type layer 13 is located above the lower end of the lower polysilicon layer 7.

According to such a configuration, when the on operation of the gate of the diode is performed before the recovery operation, electrons of the N-type layer 13 is recombined with the hole from the P-type layer 2. Accordingly, as illustrated in FIG. 7, according to the present embodiment 3, increase of the recovery loss Erec can be suppressed compared with the embodiment 1.

Electrical field generally increases in a main junction made up of the P-type layer 2 and the N-type layer 13 in a reverse withstand voltage mode. Since the lower end of the N-type layer 13 is located above the lower end of the lower polysilicon layer 7 in the present embodiment 3, field plate effect occurs in the lower polysilicon layer 7 and increase of electrical field in the N-type layer 13 can be suppressed. Thus, withstand voltage retainability can be increased.

In the present disclosure in English, articles “a” and “an” indicate one or more matters. Thus, “a”, “an”, “one or more”, and “at least one” can be used in the same sense.

Each embodiment and each modification example can be arbitrarily combined, or each embodiment and each modification can be appropriately varied or omitted.

The aspects of the present disclosure are collectively described hereinafter as appendixes.

### Appendix 1

A semiconductor device, comprising:
a first semiconductor layer of a first conductivity type;
a second semiconductor layer of a second conductivity type provided on an upper side of the first semiconductor layer;
an insulating film provided on a trench with an opening in an upper surface of the second semiconductor layer and provided between an upper part and a lower part of the trench;
an upper polysilicon layer provided to the upper part of the trench; and
a lower polysilicon layer provided to the lower part of the trench and insulated from the upper polysilicon layer by the insulating film, wherein
the upper polysilicon layer is electrically connected to a gate electrode,
the lower polysilicon layer and the second semiconductor layer are electrically connected to an anode electrode, and
a lower end of the second semiconductor layer is located below a lower end of the upper polysilicon layer.

### Appendix 2

The semiconductor device according to Appendix 1, further comprising
a third semiconductor layer of a first conductivity type selectively provided on an upper part of the second semiconductor layer, wherein
the third semiconductor layer is electrically connected to the anode electrode.

### Appendix 3

The semiconductor device according to Appendix 1 or 2, further comprising
a fourth semiconductor layer of a first conductivity type provided between the first semiconductor layer and the second semiconductor layer and having an impurity concentration of the first conductivity type higher than the first semiconductor layer, wherein
a lower end of the fourth semiconductor layer is located above a lower end of the lower polysilicon layer.

### Appendix 4

The semiconductor device according to any one of Appendixes 1 to 3, wherein
a height between the lower end of the second semiconductor layer and the lower end of the upper polysilicon layer is equal to or larger than 3 μm.

While the disclosure has been shown and described in detail, the foregoing description is in all aspects illustrative and not restrictive. It is therefore understood that numerous modifications and variations can be devised.

What is claimed is:

1. A semiconductor device, comprising:
a first semiconductor layer of a first conductivity type;
a second semiconductor layer of a second conductivity type provided on an upper side of the first semiconductor layer;
an insulating film provided on a trench with an opening in an upper surface of the second semiconductor layer and provided between an upper part and a lower part of the trench;
an upper polysilicon layer provided to the upper part of the trench; and
a lower polysilicon layer provided to the lower part of the trench and insulated from the upper polysilicon layer by the insulating film, wherein
the upper polysilicon layer is electrically connected to a gate electrode,
the lower polysilicon layer and the second semiconductor layer are electrically connected to an anode electrode, and
a lower end of the second semiconductor layer is located below a lower end of the upper polysilicon layer.

2. The semiconductor device according to claim 1, further comprising:
a third semiconductor layer of a first conductivity type selectively provided on an upper part of the second semiconductor layer, wherein
the third semiconductor layer is electrically connected to the anode electrode.

3. The semiconductor device according to claim 1, further comprising:
a fourth semiconductor layer of a first conductivity type provided between the first semiconductor layer and the second semiconductor layer and having an impurity concentration of the first conductivity type higher than the first semiconductor layer, wherein
a lower end of the fourth semiconductor layer is located above a lower end of the lower polysilicon layer.

4. The semiconductor device according to claim 1, wherein
a height between the lower end of the second semiconductor layer and the lower end of the upper polysilicon layer is equal to or larger than 3 μm.

5. The semiconductor device according to claim 2, further comprising
a fourth semiconductor layer of a first conductivity type provided between the first semiconductor layer and the second semiconductor layer and having an impurity concentration of the first conductivity type higher than the first semiconductor layer, wherein
a lower end of the fourth semiconductor layer is located above a lower end of the lower polysilicon layer.

6. The semiconductor device according to claim 2, wherein
a height between the lower end of the second semiconductor layer and the lower end of the upper polysilicon layer is equal to or larger than 3 μm.
